(19) United States
(12) Patent Application Publication
(10) Pub. No.: US 2002/0141334 A1
(43) Pub. Date: Oct. 3, 2002

(54) Dynamic protection bandwidth allocation in BLSR networks

(76) Inventors: Evert E. Deboer, Nepean (CA); Peter W. Phelps, Nepean (CA); Joseph Olajubu, Canvey Island (GB); Dave Langridge, Stansted (GB)

Correspondence Address: SUGHRUE, MION, ZINN,, MACPEAK & SEAS, PLLC, 2100 Pennsylvania Avenue, N.W., Washington, DC, 20037-3213, US

(21) Appl. No.: 09/818,527

(22) Filed: Mar. 28, 2001

(51) Int. Cl. G01R 31/08

(52) U.S. Cl. 370/227; 714/4; 370/228; 340/825.01

(57) ABSTRACT

A method of restoring data transport following a network resource failure in a communication network includes searching for protection bandwidth in a data transport ring where the transport resource failure occurred, and the search is extended to protection bandwidth on adjacent data transport rings, as required, until protection bandwidth for restoring data transport are located or all adjacent rings have been searched. Thus the ratio of working:protection bandwidth is improved by elimination of protection bandwidth between matched pair nodes interconnecting adjoining BLSRs of the network. However, high reliability which is characteristic of a BLSR network is preserved by providing a recovery algorithm that promptly allocates protection bandwidth of one or more rings, as required, in order to circumvent a failed network resource.

### CROSS-REFERENCE TO RELATED APPLICATIONS

This is the first application filed for the present invention.

### MICROFICHE APPENDIX

Not Applicable.

### TECHNICAL FIELD

The present invention relates to data transport in a communications network comprising two or more adjoining Bi-directional Line Switched Rings (BLSRs), and, in particular, to methods and operations for dynamically allocating protection bandwidth to restore data transport following a network resource failure.

### BACKGROUND OF THE INVENTION

In the modern communications space, data communications networks are frequently deployed on a physical layer network infrastructure constructed using a ring architecture. Typically, two or more Bi-directional line switched rings (BLSRs) are constructed, with interconnections provided to enable inter-ring data transport. This architecture is highly regarded for its high bandwidth capacity and reliability.

The high reliability of BLSR networks is a product of a high degree of resource redundancy, coupled with rapid physical fault detection and signal switching. Typically, a one-to-one ratio is maintained between working and protection bandwidth (usually comprising the entire bandwidth capacity of one or more so-called working and protection fibers respectively) within the BLSR network. Consequently, if a network resource failure affecting working bandwidth is detected, data traffic can be switched onto the protection bandwidth to bypass the failed resource. Resource failure detection and traffic switching may be performed by any node of the network, and thus will occur in the nodes immediately adjacent the failed resource, thereby minimizing recovery time.

Resource redundancy is typically extended to include redundant interconnections between adjoining BLSRs. Thus adjoining rings are interconnected by a matched pair of Service Access Point (SAP) nodes, one of which is identified as a primary node, and the other one of which is identified as a secondary node. Under normal operations of the network, inter-ring traffic is routed through the primary node. In the event of failure of the primary node, inter-ring traffic is routed through the secondary node.

A disadvantage of the BLSR network architecture is that its high reliability is dependent on the provisioning of fully redundant network resources. This requirement for a 1:1 ratio of working: protection bandwidth capacity requires network service providers to install and maintain duplicate sets of network nodes and optical fibers, much of which remains idle for significant periods of time. Customer demand for ever-increasing bandwidth, coupled with the high cost of installing redundant equipment, has lead network providers to seek network solutions that more efficiently utilize the total installed bandwidth capacity (taking both working and protection bandwidth capacities together) of the network.

Various techniques are known for finding the most efficient path in a BLSR network for fault restoration and data transmission. For example: Head End Ring Switching (HERS) and Ring Switched Matched Nodes (RSMN). However, these solutions do not address the problem of resource redundancy.

Applicant's co-pending U.S. patent application Ser. No. 09/471,139, entitled “Method of Deactivating Protection Fiber Resources in Optical Ring Networks” filed Dec. 23, 1999, teaches a method of reducing resource redundancy in BLSR networks by sharing protection bandwidth between the matched pair of SAP nodes interconnecting two adjoining rings. This solution is based on the recognition that simultaneous failures in both rings is highly unlikely, so that satisfactory reliability can be obtained without duplicating protection bandwidth between the SAP nodes. Thus the remaining protection bandwidth between the SAP nodes is shared by both adjoining rings, and may be used by either ring in the event of a network resource failure.

The teaching of U.S. patent application Ser. No. 09/471,139 provides a technique for improving the efficiency of utilization of network resources. However, in order to compete with alternative network topologies, such as the mesh topology, further improvements in resource utilization efficiency are required. On the other hand, such further improvements in resource utilization efficiency should not be obtained by sacrificing network reliability.

Accordingly, a technique for maximizing the efficiency of utilization of network resources in a BLSR network, while retaining high standards of reliability, remains highly desirable.

### SUMMARY OF THE INVENTION

It is an object of the invention to provide a method and system that enables dynamic protection bandwidth allocation in BLSR networks with sparsely provisioned protection bandwidth to reliably restore data communications subsequent to a resource failure.

Accordingly, an aspect of the present invention provides a method of allocating protection bandwidth for restoring data traffic following detection of a resource failure affecting working bandwidth between first and second nodes in a communications network comprising at least two adjoining data transport rings interconnected by a respective matched pair of Service Access Point (SAP) nodes and having sparsely provisioned protection bandwidth. The method comprises searching for provisioned protection bandwidth within a current data transport ring. If provisioned protection bandwidth is not found within the current data transport ring, searching for provisioned protection bandwidth within an adjoining data transport ring.

Another aspect of the present invention provides a system for allocating protection bandwidth for restoring data traffic following detection of a resource failure affecting working bandwidth between first and second nodes in a communications network comprising at least two adjoining data transport rings interconnected by a respective matched pair of Service Access Point (SAP) nodes and having sparsely provisioned protection bandwidth. the system comprises: means for searching for provisioned protection bandwidth within a current data transport ring; and means for searching for provisioned protection bandwidth within an adjoining data transport ring, if provisioned protection bandwidth is not found within the current data transport ring.

A further aspect of the present invention provides node adapted to restore data traffic following detection of a resource failure affecting working bandwidth between first and second nodes of a communications network comprising at least two adjoining data transport rings interconnected by a respective matched pair of Service Access Point (SAP) nodes and having sparsely provisioned protection bandwidth. The node comprises: means for searching for provisioned protection bandwidth within a current data transport ring; and means for searching for provisioned protection bandwidth within an adjoining data transport ring, if provisioned protection bandwidth is not found within the current data transport ring.

Preferably, each data transport ring is a Bi-directional Line Switched Ring (BLSR) incorporating the matched pair of SAP nodes, and lacking provisioned protection bandwidth between the matched pair of SAP nodes.

The current data transport ring may be a ring on which the resource failure was detected, and/or a ring on which data traffic is received by the current network node through protection bandwidth allocated to the protection path.

In embodiments of the invention, located provisioned protection bandwidth is allocating to a protection path.

In embodiments of the invention, a search stack is generating at the first node. The search stack includes a root entry comprising information respectively identifying the first and the second nodes as ingress and egress nodes. The search stack may be forwarded to an adjacent node through the protection path.

The search stack may be received at a current node through the protection path. The search stack may be searched to determine if the current node is identified as an egress node in the search stack. If the current node is identified as an egress node, at least one entry may be removed from the search stack. The search stack may be searched by comparing a node identifier of the current node with each egress node identifier stored in the search stack. In some embodiments, each (or every) entry of the search stack having information identifying the current node as an egress node is removed.

In some embodiments, the search stack is searched to determine if the search stack is empty. If the search stack is empty, data transport between the first and second nodes can be restored using the protection path. Restoration of data transport may include switching data traffic received through the protection path to working bandwidth of a downstream link.

In some embodiments, if the current node is not identified as an egress node and provisioned protection bandwidth is located by the current node within the adjacent data transport ring, a second entry may be added to the search stack. This second entry may include information respectively identifying the current node and a corresponding matched node as ingress and egress nodes.

In some embodiments, if provisioned protection bandwidth cannot be located in either the current or adjacent data transport rings, a failure alarm message may be generated.

Thus the present invention enables an improved ratio of working:protection bandwidth in a BLSR communications network, by providing efficient and reliable restoration of data transport across sparsely provisioned protection bandwidth of the network. Following detection of a network resource failure in a ring, protection bandwidth in the current ring is identified an allocated to a protection path as far as possible. When no further protection bandwidth is accessible on the current ring, the search for protection bandwidth is extended to one or more adjacent rings. Thus protection path will traverse two or more adjoining rings of the network, as required, in order to circumvent the failed network resource.

### BRIEF DESCRIPTION OF THE DRAWINGS

Further features and advantages of the present invention will become apparent from the following detailed description, taken in combination with the appended drawings, in which:

FIG. 1 is a block diagram schematically illustrating operation of the present invention.

FIG. 2 is a flow diagram illustrating the principal steps in an exemplary method in accordance with the present invention.

FIG. 3A is a block diagram schematically illustrating the path followed by the data traffic following restoration of communications using the method of FIG. 2.

FIG. 3B is a block diagram schematically illustrating the use of Head End Ring Switching (HERS), in conjunction with the present invention, to modify the path of FIG. 3A.

It will be noted that throughout the appended drawings, like features are identified by like reference numerals.

### DETAILED DESCRIPTION OF THE PREFERRED EMBODIMENT

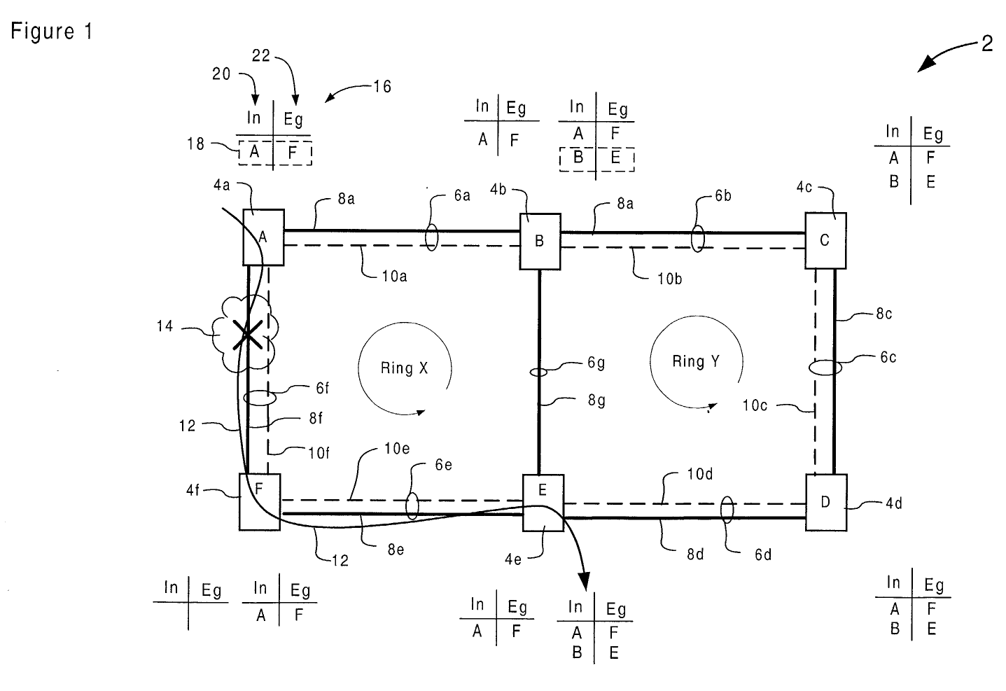

The present invention provides a method and system that enables dynamic protection bandwidth allocation in BLSR networks with sparsely provisioned protection bandwidth to reliably restore data communications subsequent to a resource failure. For the purposes of the present invention, the protection bandwidth is considered to be “sparsely provisioned” in that no protection bandwidth is provisioned between matched pairs of nodes coupling adjoining BLSR rings. Protection bandwidth is provisioned in a conventional manner in other portions of the network. FIG. 1 is a block diagram showing an exemplary BLSR network having sparsely provisioned protection bandwidth.

As shown in FIG. 1, the network 2 comprises a plurality of nodes 4 linked by optical fiber spans 6, provisioned with working bandwidth 8 and protection bandwidth 10 in most spans. In the illustrated embodiment, the network 2 is composed of a pair of adjoining rings: Ring X and Ring Y. Ring X comprises nodes 4a, 4b, 4e and 4f, which are linked via spans 6a, 6g, 6e, and 6f.

Similarly, Ring Y comprises nodes 4b, 4c, 4d and 4e, which are linked via spans 6b, 6c, 6d and 6g. It will be seen that nodes 4b and 4e, as well as span 6g, are shared by both rings, Ring X and Ring Y. Thus nodes 4b and 4e are primary and secondary matched nodes configured to interconnect the Rings X and Y to enable inter-ring data traffic. Between the matched nodes 4b and 4e, span 6g comprises only working bandwidth 8g, with no provisioned protection bandwidth 10. Within each of the remaining spans 6a, 6b, 6c, 6d, 6e and 6f both working and protection bandwidth 8, 10 are provisioned in a conventional manner.

In the example shown in FIG. 1, a unidirectional working path 12 is established between nodes 4a and 4e over working bandwidth 8 within spans 6f and 6e. For the purposes of illustrating the present invention, a resource failure 14 is assumed to interrupt data transport through span 6f between a first node 4a and a second node 4f, affecting at least the working bandwidth 8f of span 6f. As a result, the path 12 looses connectivity.

In accordance with conventional BLSR failure recovery procedures, failure of data transport through span 6f will be detected in node 4a, which would normally attempt to switch the affected data traffic from span 6f onto protection bandwidth bypassing the failed link 6f. Thus node 4a would attempt to switch data traffic of the span 6f on to protection bandwidth 10a in span 6a. As mentioned above, this standard BLSR recovery procedure requires that all spans 6 in ring X include provisioned protection bandwidth 10. The fact that protection bandwidth 10 is not provisioned over span 6g between matched nodes 4b and 4e prevents successful implementation of standard BLSR recovery procedures. Thus the present invention provides a method of identifying and allocating protection bandwidth 10 to restore traffic flow through working path 12 on a network 2 with sparsely provisioned protection bandwidth 10.

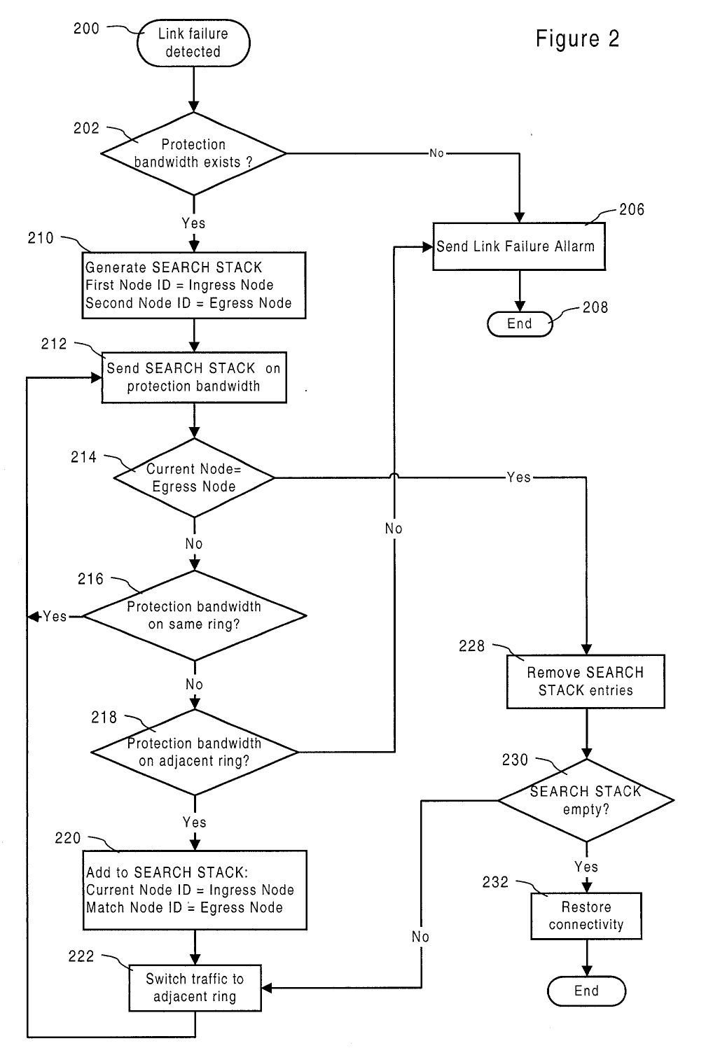

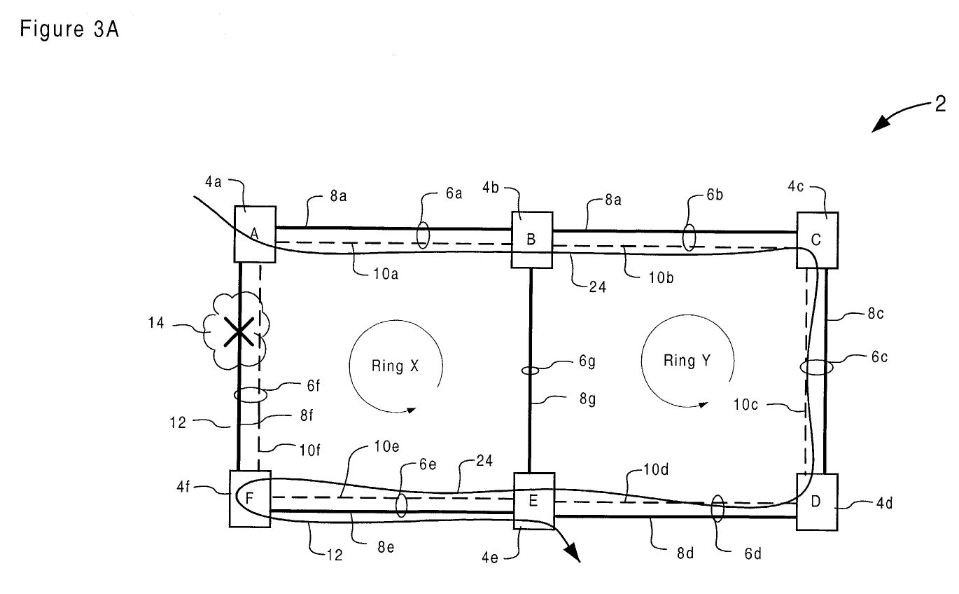

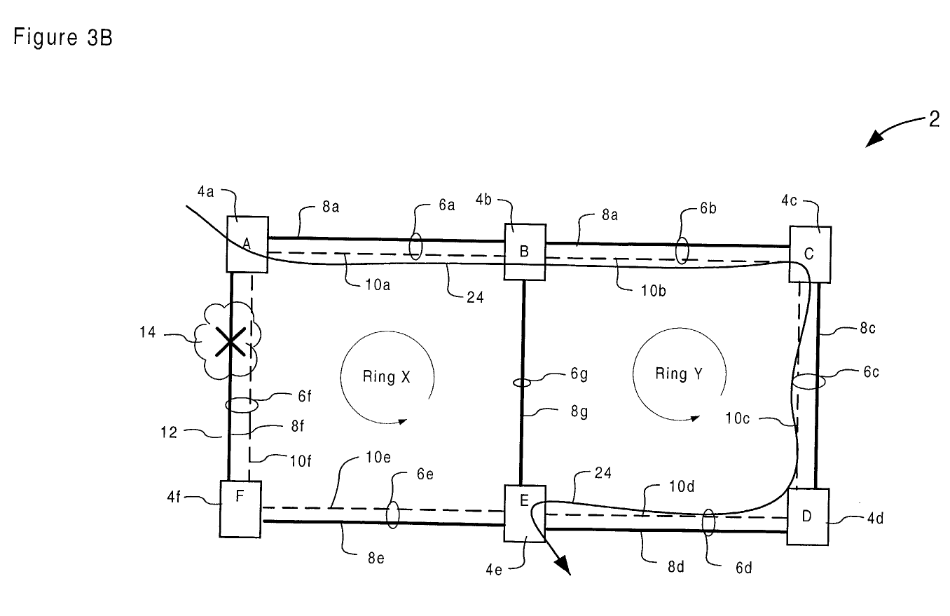

FIG. 2 is a flow diagram showing principle steps in an exemplary method for allocating protection bandwidth 10 to recover data communications in accordance with an embodiment of the present invention. Upon detection of the resource failure 14 (at step 200), node 4a checks for accessible protection bandwidth 10 (step 202). If no protection bandwidth 10 can be accessed by node 4a, a link failure alarm message is generated (step 206) and the failure recovery is terminated (step 208). In the present example, protection bandwidth 10a in link 6a is located (at step 202), and a search stack 16 (see FIG. 1) is generated (at step 210) with a root entry 18. As shown in FIG. 1, the search stack 16 may comprise a pair of columns used for storing information identifying nodes 4 involved in the search for and allocation of protection bandwidth 10. This information may take the form of node identifiers, or any other information uniquely identifying the involved nodes 4. In the illustrated embodiment, the search stack 16 comprises an ingress node column 20 and an egress node column 22. The ingress node column 20 stores node identifiers of nodes 4 through which data traffic enters the protection bandwidth 10 of a ring. Conversely, the egress node column 22 stores node identifiers of nodes 4 through which data traffic leaves the protection bandwidth 10 of a ring. The root entry 18 identifies the first data transport node 4a in the ingress node column 20 and the second node 4f in the egress node column 22. Thus the root entry 18 in the search stack 16 defines the start and finish points of a protection path 24 (see FIG. 3A) circumventing the failed link 6f.

The search stack 16 is then forwarded to node 4b (step 212) using the protection bandwidth 10a located in step 202. Upon receiving the search stack 16, node 4b examines the search stack 16 and determines if the current node 4b is identified in the egress node column 22 (step 214). In the present example of FIG. 1, node 4b is not identified in the egress node column 22 and therefore node 4b searches for protection bandwidth 10 on the same data transport ring on which the search stack 16 was received. If protection bandwidth is located in the same data transport ring, the search stack 16 is forwarded on the protection bandwidth (step 212). If protection bandwidth can not be located on the same data transport ring, the current node (in this case node 4b) checks whether protection bandwidth 10 is provisioned on an adjacent data transport ring (at step 218). In the present example, as may be seen in FIG. 1, when node 4b determines (at step 216) that protection bandwidth is not available in the same ring (i.e. in link 6g), node 4b searches for and locates protection bandwidth 10b in the adjacent ring (at step 218). Once the protection bandwidth 10b is located, an entry is added to the search stack 16 identifying node 4b as an ingress node and its matched node 4e as an egress node (step 220). The data traffic received by node 4b through protection bandwidth 10a (in Ring X) is then switched by node 4b to protection bandwidth 10b in Ring Y (step 222) and the search stack 16 is forwarded to node 4c over protection bandwidth 10b.

When node 4c receives the search stack 16, node 4c checks if the identifier of node 4c is in the egress node column 22 of the search stack 16. (at step 214) If it is not identified in the egress node column 22, node 4c searches for a protection bandwidth 10 within the same ring (at step 216) on which the search stack 16 was received. In the present example, node 4c locates protection bandwidth 10c on span 6c, and forwards the search stack 16 to node 4d (at step 212) over protection bandwidth 10c.

Upon receipt of the search stack 16, node 4d repeats the same operations as those performed by node 4c. Thus the search stack 16 is checked to determine if the identifier of current node (node 4d) is in the egress node column 22 (at step 214); protection bandwidth is located on the same ring (at step 216); and the search stack 16 is forwarded to the next adjacent node (in this case node 4e) on the protection bandwidth 10d (at step 212).

When node 4e receives the search stack 16 through protection bandwidth 10d, node 4e checks (at step 214) to determine if node 4e is identified in the egress node column 22. In the present example, node 4e is identified in the egress node column 22. Thus the corresponding entry (including the node identifiers in both the ingress node column 20 and the egress node column 22) is removed from the search stack 16 (at step 224). In some multi-ring network topologies, it may be possible for a SAP node to provide connectivity between more than two rings. In such cases, more than one entry in the search stack 16 may identify the SAP node as an egress node. In such cases, when the search stack 16 is received and processed by the sap node, all entries associated with the SAP node are removed from the search stack 16 at step 224.

In any event, after any entries associated with the current node (in the present case, node 4e) have been removed from the search stack 16, a check is performed to determine if the search stack 16 is empty (at step 228). In the present example, the search stack 16 is found to contain the root entry 18. Thus data traffic received by node 4e through protection bandwidth 10d (in Ring Y) is then switched by node 4e to protection bandwidth 10e in Ring X (step 222) and the search stack 16 is forwarded to node 4f over protection bandwidth 10e.

Upon receipt of the search stack 16, node 4f checks the search stack 16 to determine if it is identified in the egress node column 22 (step 214). In the present example, node 4f is identified in the egress node column 22, so node 4f again removes the associated entry (in this case the root entry 18), including the node identifiers in both ingress node and egress node columns 20 and 22, from the search stack 16 (step 224). Node 4f then checks if the search stack 16 is empty (at step 228). In this case, removal of the root entry 18 from the search stack 16 has left the search stack 16 empty. This condition indicates that a protection path 24 (see FIG. 3A) circumventing the failed link 6f has been identified on protection bandwidth 10. Accordingly, node 4f switches data traffic received through protection bandwidth 10e into working bandwidth 8e in order to restore data communications through path 12 (at step 230) and the recovery process is successfully terminated (at step 232).

Following successful termination of the restoration process described above with reference to FIGS. 1 and 2, data traffic of path 12 is restored via the protection path 24 illustrated in FIG. 3A. This protection path is mapped across both rings using the protection bandwidth 10 of links 6a-6e, and does not interfere with normal data traffic flows in the working bandwidth 8 of these links 6 the. At node 4f, data traffic received through protection bandwidth 10e is switched into the working bandwidth 8e. As can be seen in FIG. 3A, this protection path 24 includes a redundant loop between nodes 4e and 4f, as traffic is forwarded by node 4e through protection bandwidth 10e to node 4f, which then “hair-pins” the traffic back to node 4e through working bandwidth 8e.

To avoid this redundant traffic loop, the Head End Ring Switching (HERS) routing protocol may be deployed for use in conjunction with the present invention. This is shown in FIG. 3B. By extending conventional HERS for use with the present invention, the data traffic arriving at node 4e through the protection bandwidth 10d can be switched directly to working bandwidth and out of the network 2 by node 4e, thereby severing the redundant loop between nodes 4e and 4f.

Thus it will be seen that the present invention provides a method and system that enables dynamic protection bandwidth allocation in BLSR networks with sparsely provisioned protection bandwidth to reliably restore data communications subsequent to a resource failure. The ratio of working:protection bandwidth is improved by elimination of protection bandwidth between matched pair nodes interconnecting adjoining BLSRs of the network. However, high reliability which is characteristic of a BLSR network is preserved by providing a recovery algorithm that rapidly allocates protection bandwidth of one or more rings, as required, in order to circumvent a failed network resource.

The embodiment of the invention described above is intended to be exemplary only. The scope of the invention is therefore intended to be limited solely by the scope of the appended claims.

I claim:

1. A method of allocating protection bandwidth for restoring data traffic following detection of a resource failure affecting working bandwidth between first and second nodes in a communications network comprising at least two adjoining data transport rings interconnected by a respective matched pair of Service Access Point (SAP) nodes and having sparsely provisioned protection bandwidth, the method comprising steps of:
searching for provisioned protection bandwidth within a current data transport ring; and
if provisioned protection bandwidth is not found within the current data transport ring, searching for provisioned protection bandwidth within an adjoining data transport ring.

2. A method as claimed in claim 1, wherein each data transport ring is a Bi-directional Line Switched Ring (BLSR) incorporating the matched pair of SAP nodes, and lacking provisioned protection bandwidth between the matched pair of SAP nodes.

3. A method as claimed in claim 1, wherein the current data transport ring comprises any one or more of:
a ring on which the resource failure was detected; and
a ring on which data traffic is received by the current network node through protection bandwidth allocated to the protection path.

4. A method as claimed in claim 1, further comprising a step of allocating located provisioned protection bandwidth to a protection path.

5. A method as claimed in claim 4, further comprising steps of:
at the first node, generating a search stack including a root entry comprising information respectively identifying the first and the second nodes as ingress and egress nodes; and
forwarding the search stack to an adjacent node through the protection path.

6. A method as claimed in claim 5, further comprising a step of receiving the search stack through the protection path at a current node.

7. A method as claimed in claim 6, further comprising steps of;
searching the search stack to determine if the current node is identified as an egress node in the search stack; and
if the current node is identified as an egress node, removing at least one entry from the search stack.

8. A method as claimed in claim 7, wherein the step of searching the search stack comprises a step of comparing a node identifier of the current node with each egress node identifier stored in the search stack.

9. A method as claimed in claim 7, wherein the step of removing at least one entry from the search stack comprises a step of removing each entry comprising information identifying the current node as an egress node.

10. A method as claimed in claim 9, further comprising steps of:
searching the search stack to determine if the search stack is empty; and
if the search stack is empty, restoring data transport between the first and second nodes using the protection path.

11. A method as claimed in claim 10, wherein the step of restoring data transport comprises a step of switching data traffic received through the protection path to working bandwidth of a downstream link.

12. A method as claimed in claim 7, further comprising, if the current node is not identified as an egress node and provisioned protection bandwidth is located by the current node within the adjacent data transport ring, a step of adding a second entry to the search stack, the second entry comprising information respectively identifying the current node and a corresponding matched node as ingress and egress nodes.

13. A method as claimed in claim 1, further comprising, if provisioned protection bandwidth cannot be located in either the current or adjacent data transport rings, a step of generating a failure alarm message.

14. A system for allocating protection bandwidth for restoring data traffic following detection of a resource failure affecting working bandwidth between first and second nodes in a communications network comprising at least two adjoining data transport rings interconnected by a respective matched pair of Service Access Point (SAP) nodes and having sparsely provisioned protection bandwidth, the system comprising:
means for searching for provisioned protection bandwidth within a current data transport ring; and
means for searching for provisioned protection bandwidth within an adjoining data transport ring, if provisioned protection bandwidth is not found within the current data transport ring.

15. A system as claimed in claim 14, wherein each data transport ring is a Bi-directional Line Switched Ring (BLSR) incorporating the matched pair of SAP nodes, and lacking provisioned protection bandwidth between the matched pair of SAP nodes.

16. A system as claimed in claim 14, wherein the current data transport ring comprises any one or more of:
a ring on which the resource failure was detected; and
ring on which data traffic is received by the current network node through protection bandwidth allocated to the protection path.

17. A system as claimed in claim 14, further comprising means for allocating located provisioned protection bandwidth to a protection path.

18. A system as claimed in claim 17, further comprising:
means for generating a search stack at the first node, the search stack including a root entry comprising information respectively identifying the first and the second nodes as ingress and egress nodes; and
means for forwarding the search stack to an adjacent node through the protection path.

19. A system as claimed in claim 18, further comprising means for receiving the search stack through the protection path at a current node.

20. A system as claimed in claim 19, further comprising:
means for searching the search stack to determine if the current node is identified as an egress node in the search stack; and
means for removing at least one entry from the search stack, if the current node is identified as an egress node.

21. A system as claimed in claim 20, wherein the means for searching the search stack comprises means for comparing a node identifier of the current node with each egress node identifier stored in the search stack.

22. A system as claimed in claim 21, wherein the means for removing at least one entry from the search stack comprises means for removing each entry having information identifying the current node as an egress node.

23. A system as claimed in claim 22, further comprising:
means for searching the search stack to determine if the search stack is empty; and
means for restoring data transport between the first and second nodes using the protection path, if the search stack is empty.

24. A system as claimed in claim 23, wherein the means for restoring data transport comprises means for switching data traffic received through the protection path to working bandwidth of a downstream link.

25. A system as claimed in claim 20, further comprising, means for adding a second entry to the search stack if the current node is not identified as an egress node and provisioned protection bandwidth is located by the current node within the adjacent data transport ring, the second entry comprising information respectively identifying the current node and a corresponding matched node as ingress and egress nodes.

26. A system as claimed in claim 14, further comprising means for generating a failure alarm message if provisioned protection bandwidth cannot be located in either the current or adjacent data transport rings.

27. A node adapted to restore data traffic following detection of a resource failure affecting working bandwidth between first and second nodes of a communications network comprising at least two adjoining data transport rings interconnected by a respective matched pair of Service Access Point (SAP) nodes and having sparsely provisioned protection bandwidth, the node comprising:
means for searching for provisioned protection bandwidth within a current data transport ring; and
means for searching for provisioned protection bandwidth within an adjoining data transport ring, if provisioned protection bandwidth is not found within the current data transport ring.

28. A node as claimed in claim 27, wherein each data transport ring is a Bi-directional Line Switched Ring (BLSR) incorporating the matched pair of SAP nodes, and lacking provisioned protection bandwidth between the matched pair of SAP nodes.

29. A node as claimed in claim 27, wherein the current data transport ring comprises any one or more of:
a ring on which the resource failure was detected; and
a ring on which data traffic is received by the current network node through protection bandwidth allocated to the protection path.

30. A node as claimed in claim 27, further comprising means for allocating located provisioned protection bandwidth to a protection path.

31. A node as claimed in claim 17, further comprising:
means for generating a search stack including a root entry comprising information identifying the node as an ingress node and a second node as an egress node; and
means for forwarding the search stack to an adjacent node through the protection path.

32. A node as claimed in claim 31, further comprising means for receiving the search stack through the protection path.

33. A node as claimed in claim 32, further comprising:
means for searching the search stack to determine if the node is identified as an egress node in the search stack; and
means for removing at least one entry from the search stack, if the node is identified as an egress node.

34. A node as claimed in claim 33, wherein the means for searching the search stack comprises means for comparing a node identifier of the node with each egress node identifier stored in the search stack.

35. A node as claimed in claim 34, wherein the means for removing at least one entry from the search stack comprises means for removing each entry having information identifying the node as an egress node.

36. A node as claimed in claim 33, further comprising:
means for searching the search stack to determine if the search stack is empty; and
means for restoring data transport between the first and second nodes using the protection path, if the search stack is empty.

37. A node as claimed in claim 36, wherein the means for restoring data transport comprises means for switching data traffic received through the protection path to working bandwidth of a downstream link.

38. A node as claimed in claim 33, further comprising means for adding a second entry to the search stack, the second entry comprising information respectively identifying the current node and a corresponding matched node as ingress and egress nodes.

39. A node as claimed in claim 27, further comprising means for generating a failure alarm message if provisioned protection bandwidth cannot be located in either the current or adjacent data transport rings.
